(19) United States
(12) Patent Application Publication
(10) Pub. No.: US 2009/0009264 A1
(43) Pub. Date: Jan. 8, 2009

(54) Delay Line

(75) Inventors: Hiroyuki Morikaku, Nagano-pref (JP); Itsuaki Katsumata, Nagano-pref (JP); Masahiko Yokoyama, Nagano-pref (JP)

Correspondence Address: BURR & BROWN, PO BOX 7068, SYRACUSE, NY, 13261-7068, US

(73) Assignee: SOSHIN ELECTRIC CO. LTD., NAGANO-PREF (JP)

(21) Appl. No.: 11/817,419

(22) PCT Filed: Feb. 16, 2006
(86) PCT No.: PCT/JP2006/302774

§ 371 Date: Aug. 30, 2007

(30) Foreign Application Priority Data
Mar. 10, 2005 (JP) 2005-068149

(51) Int. Cl. H03H 7/20

(52) U.S. Cl. 333/139

(57) ABSTRACT

A delay line having a first delay circuit and a second delay circuit. The first delay circuit consists of a band-pass delay line having a first input terminal and an output terminal and other delay lines. The second delay circuit has a hybrid coupler equipped with a second input terminal, a first output terminal, a second output terminal, and an isolation terminal, a first reactance section connected with the first output terminal, and a second reactance section connected with the second output terminal. Furthermore, the output terminal of the first delay circuit is electrically connected with the second input terminal of the hybrid coupler of the second delay circuit.

### TECHNICAL FIELD

The present invention relates to a delay line, which is capable of widening a passband, reducing an absolute delay time deviation, and increasing an absolute delay time.

### BACKGROUND ART

Recently, distortion-compensation amplifiers for reducing distortions in base stations, which are used in base station wireless apparatuses such as mobile communication systems or the like, employ a variable delay line, for example, for the purpose of detecting and suppressing distortions.

As shown in FIG. 20, for example, a variable delay line 300 includes capacitors 306, 308 and a variable-capacitance capacitor 310, which are connected in series with each other between an input terminal 302 and an output terminal 304, and first and second resonators 312 and 314, which are connected, respectively, between terminals of the variable-capacitance capacitor 310 and ground (see, for example, Patent Document 1).

The variable delay line 300 allows an absolute delay time to be fine-adjusted easily, simply by varying the capacitance Ca of the variable-capacitance capacitor 310. The variable delay line 300 makes it possible to increase the productivity of feed-forward circuits of distortion-compensation amplifiers, for example.

As shown in FIG. 21, another conventional variable delay line 400 comprises a hybrid coupler 402, and a first reactance unit 406a and a second reactance unit 406b, which are connected respectively to a first output terminal 404a and a second output terminal 404b of the hybrid coupler 402 (see, for example, Patent Document 2).

The hybrid coupler 402 also includes, in addition to the first output terminal 404a and the second output terminal 404b, an input terminal 406 supplied with an input signal, and an isolation terminal 408 for outputting, as an output signal (third output signal) from the variable delay line 400, a reflected signal based on a first output signal and a second output signal that are output from the first output terminal 404a and the second output terminal 404b.

The first reactance unit 406a and the second reactance unit 406b comprise respective series-connected circuits having respective first and second capacitors 408a, 408b, respective first and second varactor diodes 410a, 410b, and respective first and second dielectric resonators 412a, 412b. Respective ends of the first and second capacitors 408a, 408b are connected to the first output terminal 404a and the second output terminal 404b, while respective other ends thereof are connected to the respective cathode terminals of the first and second varactor diodes 410a, 410b. The first and second varactor diodes 410a, 410b have respective anode terminals connected respectively to the first and second dielectric resonators 412a, 412b. First and second voltage control terminals 414a, 414b are connected respectively to the cathode terminals, for supplying control voltages thereto.

When the first and second voltage control terminals 414a, 414b supply the first and second varactor diodes 410a, 410b with respective control voltages, coupling capacitances Cb of the first and second varactor diodes 410a, 410b are changed depending on the values of the control voltages. Specifically, when the values of the control voltages are increased, the coupling capacitances Cb of the first and second varactor diodes 410a, 410b are reduced.

When the coupling capacitances Cb are changed, the admittances of the first reactance unit 406a and the second reactance unit 406b are changed, thereby increasing the absolute delay time of the variable delay line 400. If the coupling capacitances Cb of the first and second varactor diodes 410a, 410b are variable within a wider range, then the variable delay line 400 has a more widely variable delay time.

For example, if the values of circuit components of the first reactance unit 406a and the second reactance unit 406b are adjusted, such that the absolute delay time of the third output signal output with respect to the isolation terminal 408 has a minimum value of about 1 ns, then a deviation of the absolute delay time with respect to a frequency band higher than 100 MHz can be reduced to 0.1 ns or shorter, and the variable delay time can be increased to 1 ns.

Even when the absolute delay time of the variable delay line 400 changes to about 2 ns, the transmission characteristics and the mismatch attenuation thereof remain virtually unchanged. Therefore, the passband of the variable delay line 400 can have a wide bandwidth of 60 MHz or higher.

Patent Document 1: Japanese Laid-Open Patent Publication No. 2001-119206

Patent Document 2: Japanese Laid-Open Patent Publication No. 2004-153815

### DISCLOSURE OF THE INVENTION

When the coupling capacitance Ca of the variable delay line 300 described in Patent Document 1 is changed, the capacitor 306 and the first resonator 312 on the side of the input terminal 302, and the capacitor 308 and the second resonator 314 on the side of the output terminal 304, are brought out of balance, varying the value of the input impedance and the value of the output impedance of the variable delay line 300. Therefore, it becomes difficult to achieve impedance matching in the variable delay line 300. Another problem is that, as the absolute delay time increases, the deviation thereof (deviation of the absolute delay time) also increases.

On the other hand, the variable delay line 400 described in Patent Document 2 is capable of reducing variations in input and output impedances, in addition to widening the passband and reducing deviations in the absolute delay time. However, the variable delay line 400 has a problem in that the absolute delay time is about 1 ns, and thus its range of applications is restricted.

The present invention has been made in view of the above problems. It is an object of the present invention to provide a delay line having a simple structure, which is capable of widening a passband, reducing an absolute delay time deviation, and increasing an absolute delay time.

A delay line according to the present invention comprises a first delay circuit including a first input terminal and an output terminal, and a second delay circuit comprising a hybrid coupler including a second input terminal, a first output terminal, a second output terminal, and an isolation terminal, a first reactance unit connected to the first output terminal, and a second reactance unit connected to the second output terminal, wherein the output terminal of the first delay circuit and the second input terminal of the hybrid coupler of the second delay circuit are electrically connected to each other.

The second delay circuit is capable of suppressing variations in the input impedance and output impedance of the delay line, and of widening a passband and reducing an absolute delay time deviation. The first delay circuit is capable of increasing an absolute delay time.

In the above arrangement, the first delay circuit and the second delay circuit may be integrally combined with each other. In this case, it is advantageous for reducing the delay line in size.

In the above arrangement, the first reactance unit and the second reactance unit of the second delay circuit may include respective reactance elements having constant reactances. Alternatively, the first reactance unit and the second reactance unit of the second delay circuit may include respective control terminals to which control voltages are applied, and respective variable reactance elements having reactances that are variable depending on the control voltages applied to the control terminals.

The first delay circuit may comprise a bandpass filter. The bandpass filter may include a plurality of resonators between the first input terminal and the output terminal. Alternatively, the bandpass filter may include a plurality of LC resonating circuits between the first input terminal and the output terminal.

The first input terminal and one of the resonators adjacent to the first input terminal, the output terminal and one of the resonators adjacent to the output terminal, and the plurality of resonators may be connected to each other by capacitances or inductances.

Alternatively, the first input terminal and one of the resonators adjacent to the first input terminal may be connected to each other by a capacitance or an inductance, the output terminal and one of the resonators adjacent to the output terminal may be connected to each other by a capacitance or an inductance, and the plurality of resonators may be connected to each other by capacitances or inductances, thereby providing a symmetrical array of capacitive couplings and inductive couplings. The delay line thus constructed has a simple structure, and can provide flatness for the absolute delay time within the passband, as well as being reduced in size. The phrase “flatness for the absolute delay time within the passband” represents the degree to which a region (flat region), in which deviation from the absolute delay time at the central frequency of the passband falls within 0.5 ns, takes up a lower frequency range or a higher frequency range from the central frequency. According to the present invention, the flat region occupies a wide range (substantially 50% to 80% of the passband) inside of the passband.

The first delay circuit may comprise at least one of a low-pass filter, a circuit having a delay caused by a stripline length, and a SAW delay line.

As described above, the delay line according to the present invention has a simple structure, and is capable of widening a passband, reducing an absolute delay time deviation, and increasing an absolute delay time.

### BRIEF DESCRIPTION OF THE DRAWINGS

FIG. 1 is a circuit diagram showing a delay line according to an embodiment of the present invention;

FIG. 2 is a circuit diagram showing a delay line according to a first embodiment;

FIG. 3 is a circuit diagram showing a delay line according to a second embodiment;

FIG. 4 is a circuit diagram showing a delay line according to a first inventive example;

FIG. 5 is a diagram showing delay characteristics of the delay line according to the first inventive example;

FIG. 6 is a diagram showing attenuation characteristics of the delay line according to the first inventive example;

FIG. 7 is a diagram showing how mismatch attenuation changes with respect to frequency of the delay line, according to the first inventive example;

FIG. 8 is a circuit diagram of a delay line according to a comparative example;

FIG. 9 is a diagram showing delay characteristics, attenuation characteristics, and how mismatch attenuation changes with respect to frequency of the delay line, according to the comparative example;

FIG. 10 is a circuit diagram showing a delay line according to a second inventive example;

FIG. 11 is a diagram showing delay characteristics of the delay line according to the second inventive example;

FIG. 12 is a diagram showing attenuation characteristics of the delay line according to the second inventive example;

FIG. 13 is a diagram showing how mismatch attenuation changes with respect to frequency of the delay line, according to the second inventive example;

FIG. 14 is a circuit diagram showing a delay line according to a third inventive example;

FIG. 15 is a diagram showing delay characteristics of the delay line according to the third inventive example;

FIG. 16 is a diagram showing attenuation characteristics of the delay line according to the third inventive example;

FIG. 17 is a diagram showing how mismatch attenuation changes with respect to frequency of the delay line, according to the third inventive example;

FIG. 18 is a circuit diagram showing another first delay circuit;

FIG. 19 is a circuit diagram showing still another first delay circuit;

FIG. 20 is a circuit diagram showing a conventional delay line; and

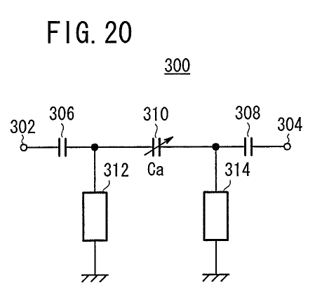

FIG. 21 is a circuit diagram showing another conventional delay line.

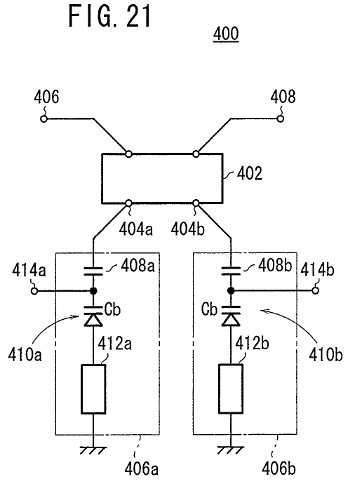

### BEST MODE FOR CARRYING OUT THE INVENTION

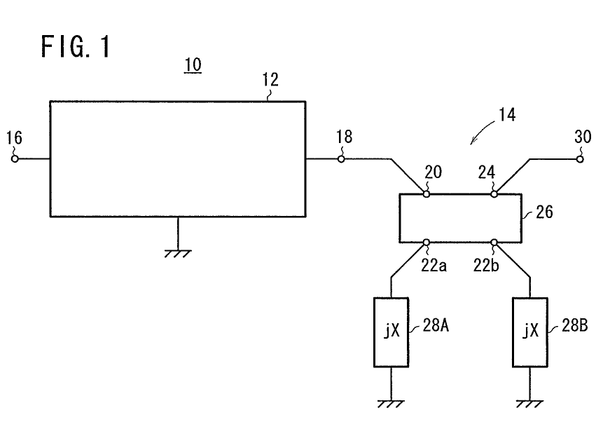

Embodiments of delay lines according to the present invention shall be described below with reference to FIGS. 1 through 19.

As shown in FIG. 1, a delay line 10 according to an embodiment of the present invention includes a first delay circuit 12 and a second delay circuit 14. The first delay circuit 12 includes a bandpass delay line (bandpass filter: BPF) having a first input terminal 16, and an output terminal 18 or another delay line.

The second delay circuit 14 comprises a hybrid coupler 26 including a second input terminal 20, a first output terminal 22a, a second output terminal 22b, and an isolation terminal 24. A first reactance unit 28A is connected to the first output terminal 22a, and a second reactance unit 28B is connected to the second output terminal 22b. The output terminal 18 of the first delay circuit 12 and the second input terminal 20 of the hybrid coupler 26 of the second delay circuit 14 are electrically connected to each other.

The isolation terminal 24 of the hybrid coupler 26 outputs a reflected signal through an output terminal 30, based on a first output signal output from the first output terminal 22a and a second output signal output from the second output terminal 22b, as an output signal (third output signal) of the delay line 10 according to the present embodiment. The first output terminal 22a is an output terminal of 0° for outputting the first output signal, which is in phase with an input terminal supplied to the second input terminal 20. The second output terminal 22b is an output terminal of 90° for outputting the second output signal, which is 90° out of phase with the input signal.

The first reactance unit 28A and the second reactance unit 28B are substantially the same as each other, and produce a constant reactance X. The first reactance unit 28A and the second reactance unit 28B have respective ends connected correspondingly to the first and second output terminals 22a, 22b, and wherein the respective other ends thereof are connected to GND (ground).

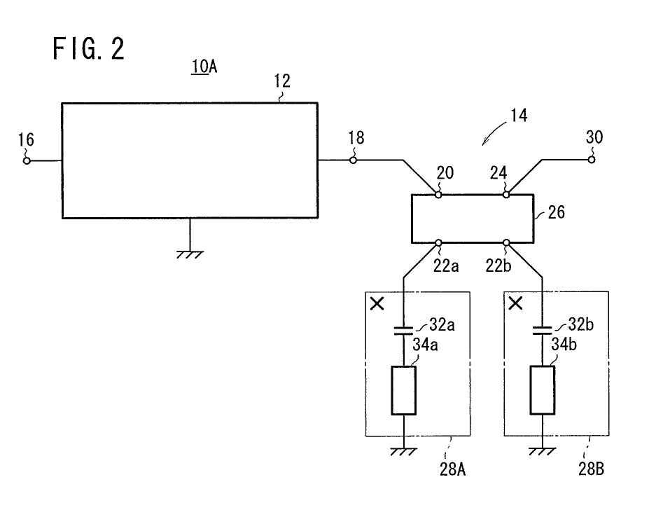

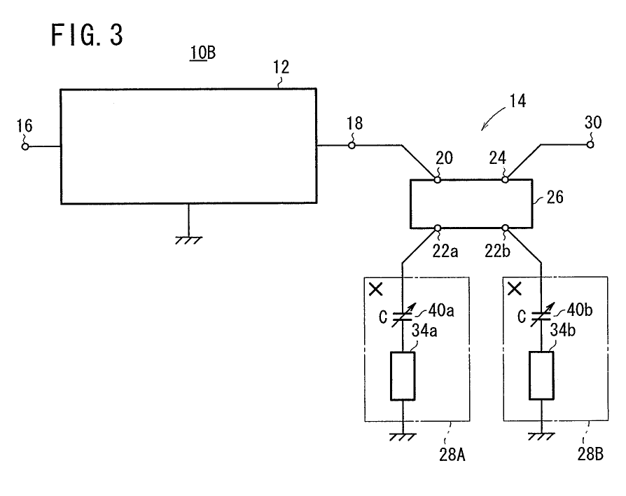

Two embodiments of the delay line 10 according to the present embodiment shall be described below with reference to FIGS. 2 and 3.

A delay line 10A according to a first embodiment shall be described below with reference to FIG. 2.

In the delay line 10A according to the first embodiment, the first reactance unit 28A comprises a series-connected circuit made up of a first capacitive element 32a acting as a reactance element and a first resonator 34a. The second reactance unit 28B comprises a series-connected circuit of a second capacitive element 32b acting as a reactance element and a second resonator 34b. Preferably, the first resonator 34a and the second resonator 34b should each be an LC resonator, a resonator comprising a distributed constant circuit, or a dielectric resonator (λ/4 resonator or λ/2 resonator).

Operation of the second delay circuit 14 shall be described below. When an input signal is supplied to the hybrid coupler 26 through the second input terminal 20, the first and second output terminals 22a, 22b output first and second output signals, respectively. The first and second output signals are 900 out of phase with each other.

Since the first output terminal 22a is grounded through the first reactance unit 28A and the second output terminal 22b is grounded through the second reactance unit 28B, the first and second output signals produce first and second reflected signals, respectively. A reflected signal, which is a combination of the first and second reflected signals, is output to the isolation terminal 24. The reflected signal is output through the output terminal 30 as an output signal of the delay line 10A, i.e., a third output signal. The reflected signal is 180° out of phase with the input signal.

A portion between the isolation terminal 24 and the second input terminal 20 functions as an isolator. Therefore, a reflected wave of the reflected signal, which propagates from the isolation terminal 24 toward the second input terminal 20, is attenuated along the way, and is not output to the second input terminal 20. The reflected wave thus does not affect the input impedance and output impedance of the delay line 10A. Consequently, the hybrid coupler 26, the first reactance unit 28A, and the second reactance unit 28B are capable of suppressing variations in the input and output impedances of the delay line 10A, thereby easily achieving impedance matching.

The first resonator 34a and the second resonator 34b have respective resonant frequencies. The resonant frequencies determine a central frequency in the passband of the delay line 10A. In other words, when the resonant frequencies are set to desired values, the delay line 10A can have a desired passband.

According to the first embodiment, since the first delay circuit 12, which comprises a BPF or another delay line, is connected and forms a front stage of the second delay circuit 14, the absolute delay time of the first delay circuit 12 can be increased.

The delay line 10A according to the first embodiment is thus of a simple structure, while being capable of widening a passband, reducing an absolute delay time deviation, and increasing an absolute delay time.

A delay line 10B according to a second embodiment shall be described below with reference to FIG. 3. Parts of the delay line 10B that correspond to those of the delay line 10A shown in FIG. 2 are denoted by identical reference characters, and such features will not be described below.

As shown in FIG. 3, the delay line 10B according to the second embodiment is of essentially the same structure as the delay line 10A according to the first embodiment, but differs therefrom in that the first reactance unit 28A of the second delay circuit 14 comprises a series-connected circuit made up of a first variable capacitive element 40a serving as a reactance element and a first resonator 34a. In addition, the second reactance unit 28B comprises a series-connected circuit made up of a second variable capacitive element 40b serving as a reactance element and a second resonator 34b.

Each of the first variable capacitive element 40a and the second variable capacitive element 40b may comprise a circuit element, which is capable of changing a reactance X by changing its coupling capacitor C, wherein each of the first and second variable capacitive elements 40a, 40b is made up of a varactor diode, a trimmer capacitor, or the like.

The delay line 10B according to the second embodiment offers the same advantages as the delay line 10A of the first embodiment, along with the additional advantage that when the coupling capacitances C of the first variable capacitive element 40a of the first reactance unit 28A and the second variable capacitive element 40b of the second reactance unit 28B are changed, the reactances X of the first reactance unit 28A and the second reactance unit 28B can be changed by the same quantity, thereby changing the absolute delay time of the third output signal.

In the delay lines 10A and 10B according to the first and second embodiments, the first delay circuit 12 and the second delay circuit 14 may be integrally combined with each other. The first delay circuit 12 and the second delay circuit 14 may be integrally combined with each other by being mounted together on one wiring board, or by being formed on a single substrate (dielectric substrate or the like). When the first delay circuit 12 and the second delay circuit 14 are integrally combined with each other, the delay lines 10A, 10B can further be reduced in size.

### INVENTIVE EXAMPLE 1

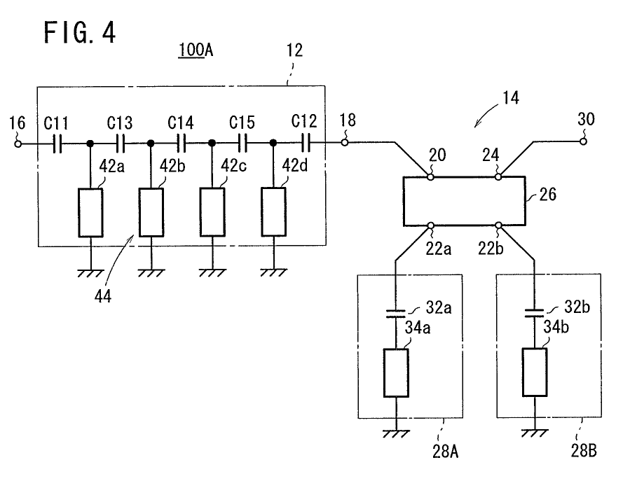

An inventive example of the delay line 10A according to the first embodiment (a delay line 100A according to a first inventive example) shall be described below with reference to FIGS. 4 through 7.

In the delay line 100A according to the first inventive example, the second delay circuit 14 comprises a hybrid coupler 26, a first reactance unit 28A, and a second reactance unit 28B, similar to the features shown in FIG. 2. The first reactance unit 28A comprises a series-connected circuit made up of a first capacitive element 32a and a first resonator 34a. The second reactance unit 28B comprises a series-connected circuit made up of a second capacitive element 32b and a second resonator 34b.

The first delay circuit 12 comprises a bandpass filter 44 including a plurality of λ/4 resonators (first through fourth resonators 42a through 42d) disposed between a first input terminal 16 and an output terminal 18. In the bandpass filter 44, the first input terminal 16 and the first resonator 42a, the fourth resonator 42d and the output terminal 18, and the resonators 42a through 42d are connected to each other by respective capacitors C11, C12, C13, C14, C15.

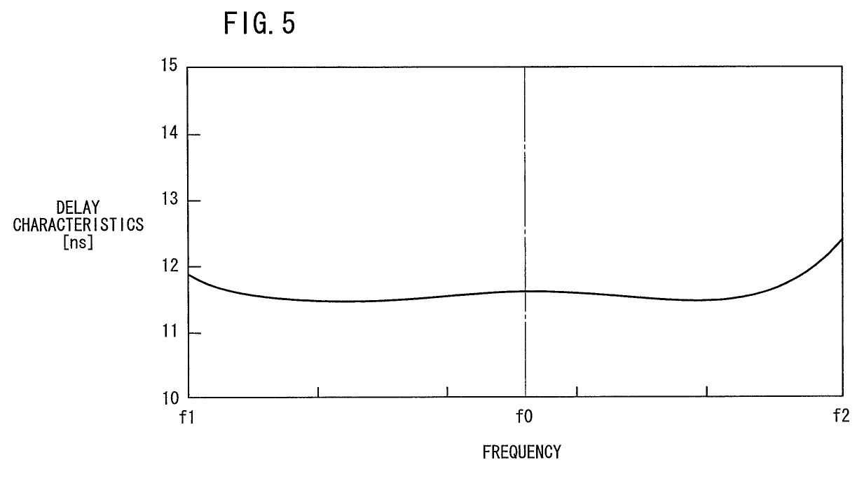

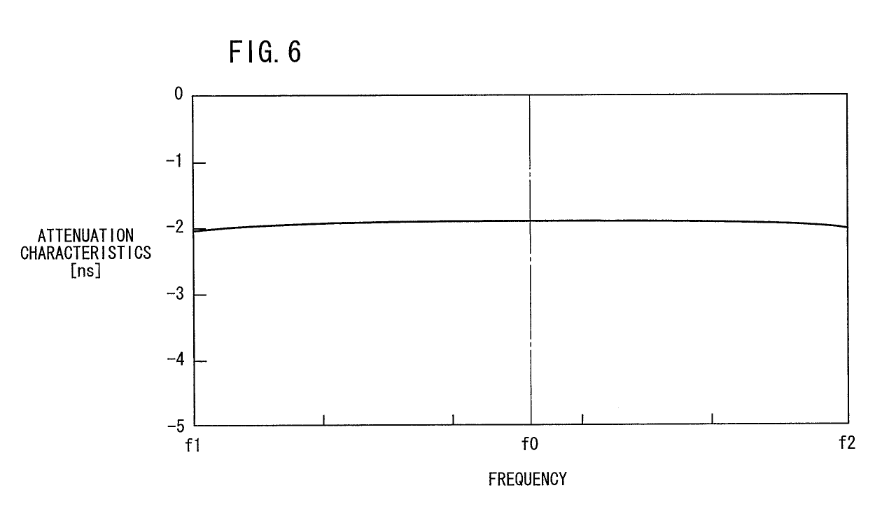

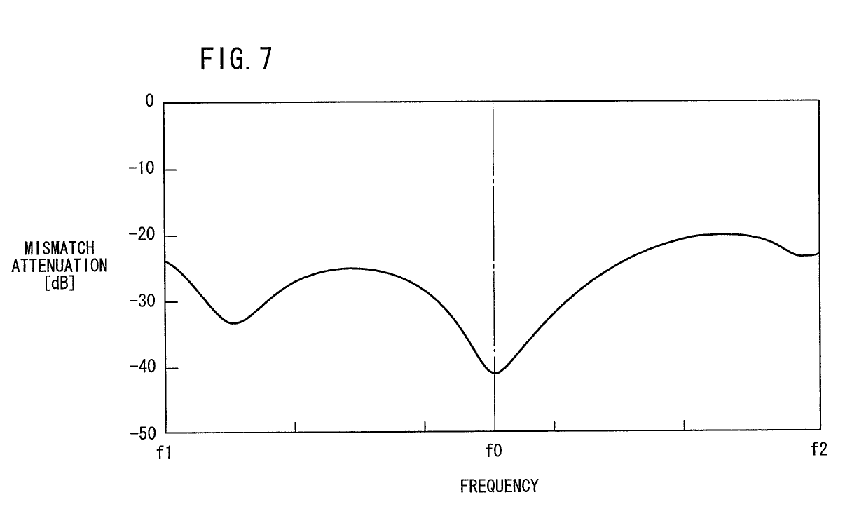

The delay line 100A according to the first inventive example has delay characteristics as shown in FIG. 5, and attenuation characteristics as shown in FIG. 6. The mismatch attenuation of the delay line 100A is changed with respect to frequency as shown in FIG. 7. In FIGS. 5 through 7, the characteristics are shown within a range of frequencies, from frequencies f1 through f2.

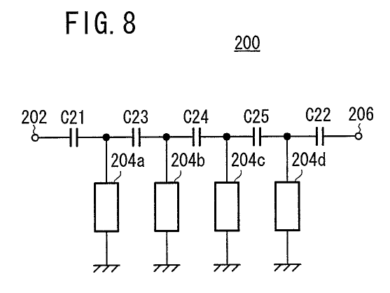

Operation and advantages of the delay line 100A according to the first inventive example shall be described below, in comparison with a delay line 200 according to a comparative example (see FIG. 8).

As shown in FIG. 8, the delay line 200 according to the comparative example is of essentially the same structure as the first delay circuit according to the first inventive example, having an input terminal 202 and a first resonator 204a, a fourth resonator 204d and an output terminal 206, and resonators 204a through 204d connected to each other by respective capacitors C21, C22, C23, C24, C25.

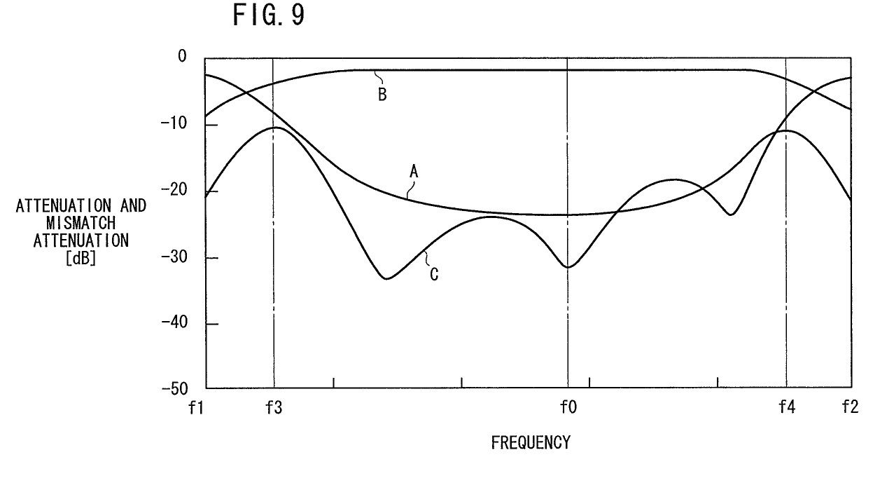

The delay line 200 according to the comparative example also has delay characteristics and attenuation characteristics, and further, the mismatch attenuation of the delay line 200 is changed with respect to frequency, as shown in FIG. 9. In FIG. 9, curve A represents the delay characteristics, curve B represents the attenuation characteristics, and curve C shows the mismatch attenuation, which is changed with respect to frequency. In FIG. 9, the characteristics are shown within a range of frequencies, from frequencies f1 through f2.

The delay line 200 according to the comparative example further has a central frequency f0 and a passband within a range of frequencies, from frequencies f3 through f4. Such frequencies are related to each other as follows: f1<f3<f0 and f0<f4<f2.

A review of the flatness of the absolute delay time according to the comparative example indicates that a region (flat region), in which the deviation from the absolute delay time at the central frequency f0 of the passband falls within 0.5 ns, occupies about 30% of the passband.

It can be seen from FIG. 6 that the delay line 100A according to the first inventive example has a passband, which is wider than the range from frequencies f1 through f2, because the signal does not fall 3 dB from the value at the central frequency f0 within the range of frequencies from frequencies f1 through f2. Specifically, the passband of the delay line 100A according to the first inventive example is represented by a range of frequencies, which ranges from frequencies f5 to f6 (not shown), wherein the frequencies are related to each other as follows: f5<f1<f0 and f0<f2<f6.

It can also be seen from FIG. 7 that the mismatch attenuation of the delay line 100A according to the first inventive example is 20 dB or greater within the range of frequencies from frequencies f1 through f2, and that the reflected energy is lower than in the comparative example.

A review of the flatness of the absolute delay time of the delay line 100A according to the first inventive example indicates that a region (flat region), in which the deviation from the absolute delay time at the central frequency f0 of the passband falls within 0.5 ns, occupies about 65% of the passband, which is much larger than the 30% value achieved according to the comparative example.

### INVENTIVE EXAMPLE 2

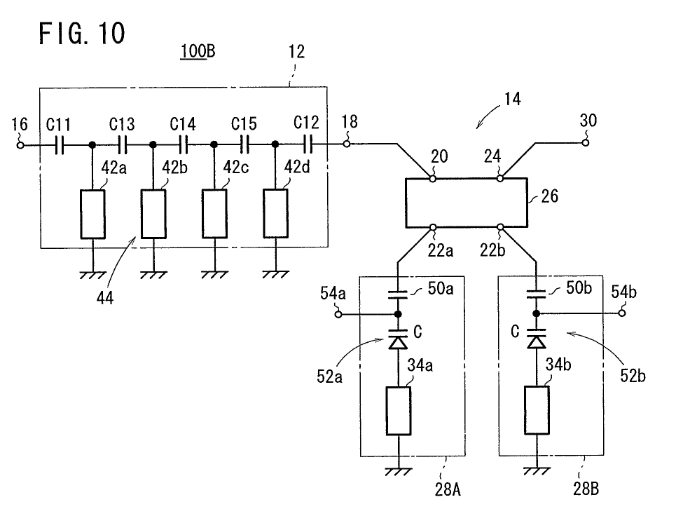

An inventive example of the delay line 10B according to the second embodiment (a delay line 100B according to a second inventive example) shall be described below with reference to FIGS. 10 through 13.

The delay line 100B according to the second inventive example is of essentially the same structure as the delay line 100A according to the first inventive example. However, as shown in FIG. 10, the first reactance unit 28A and the second reactance unit 28B of the second delay circuit 14 differ as follows:

The first reactance unit 28A comprises a series-connected circuit made up of a first capacitor 50a, a first varactor diode 52a, and a first resonator 34a. The second reactance unit 28B comprises a series-connected circuit made up of a second capacitor 50b, a second varactor diode 52b, and a second resonator 34b.

In the first reactance unit 28A, the first capacitor 50a has one end connected to the first output terminal 22a, and another end connected to the cathode terminal of the first varactor diode 52a. The first varactor diode 52a has an anode terminal thereof connected to the first resonator 34a. A first voltage control terminal 54a is connected to the cathode terminal of the first varactor diode 52a, for applying a DC control voltage thereto.

In the second reactance unit 28B, similarly, the second capacitor 50b has one end connected to the second output terminal 22b and another end connected to the cathode terminal of the second varactor diode 52b. The second varactor diode 52b has an anode terminal thereof connected to the second resonator 34b. A second voltage control terminal 54b is connected to the cathode terminal of the second varactor diode 52b, for applying a DC control voltage thereto.

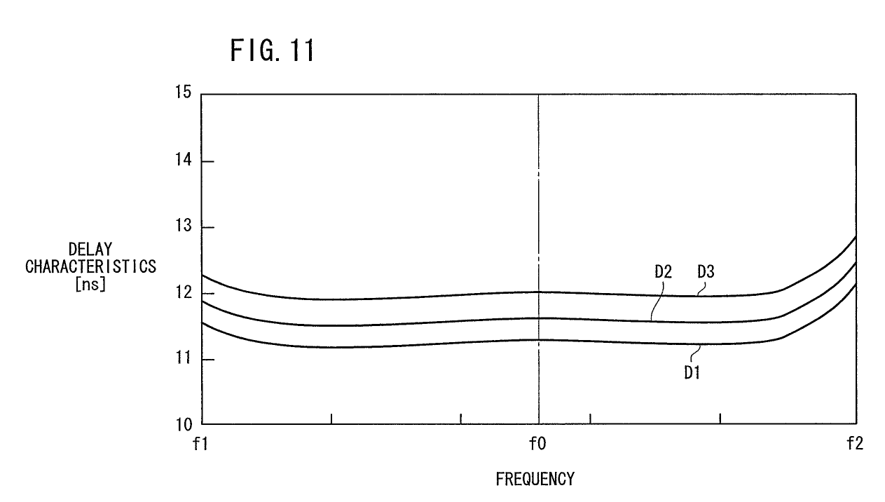

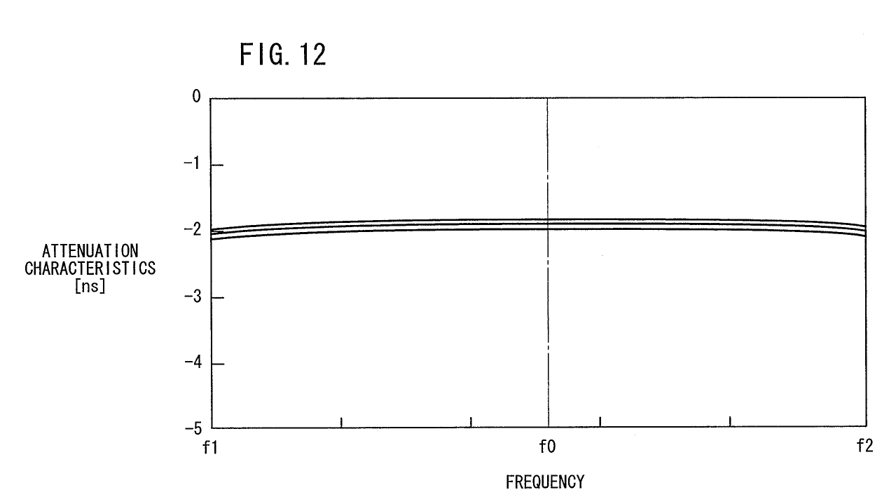

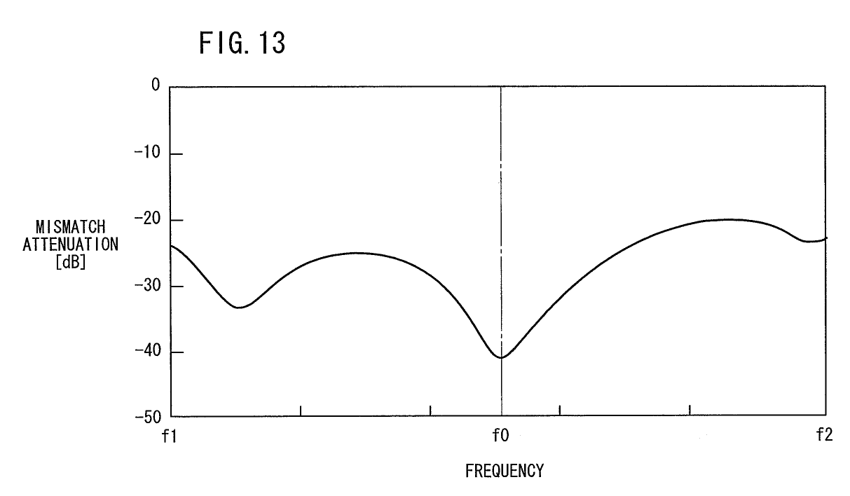

The delay line 100B according to the second inventive example has delay characteristics as shown in FIG. 11, and attenuation characteristics as shown in FIG. 12. The mismatch attenuation of the delay line 100B is changed with respect to frequency as shown in FIG. 13. In FIGS. 11 through 13, the characteristics are shown within a range of frequencies, from frequencies f1 through f2. In FIGS. 11 through 13, curve D1 represents characteristics when the coupling capacitance C of each of the first varactor diode 52a and the second varactor diode 52b is C1, curve D2 represents characteristics when the coupling capacitance C is C2, and curve D3 represents characteristics when the coupling capacitance C is C3. The capacitances are related to each other as follows: C1>C2>C3.

Operation and advantages of the delay line 100B according to the second inventive example shall be described below, in comparison with the delay line 200 according to the comparative example.

In the delay line 100B according to the second inventive example, when DC control voltages, which have substantially the same value, are applied respectively from the first voltage control terminal 54a and the second voltage control terminal 54b to the first varactor diode 52a and the second varactor diode 52b through resistors and coils (not shown), the coupling capacitances C of the first varactor diode 52a and the second varactor diode 52b are changed by the same quantity, depending on the values of the control voltages. Specifically, when the values of the control voltages increase, the coupling capacitances C of each of the first varactor diode 52a and the second varactor diode 52b decrease.

When the coupling capacitance C changes from C=C1 to C=C2 or C=C3 (C1>C2>C3), the admittances of the first reactance unit 28A and the second reactance unit 28B change, and further the absolute delay time of the delay line 100B increases, as shown in FIG. 11. If the coupling capacitances C of the first and second varactor diodes 52a, 52b are made variable within a wider range, then the variable delay time of the delay line 100B is more widely variable.

It can be seen from FIG. 12 that the delay line 100B according to the second inventive example has a passband, which is wider than the range from frequencies f1 through f2, because the signal does not fall 3 dB from the value at the central frequency f0 within the range of frequencies from frequencies f1 through f2. Specifically, the passband of the delay line 100B according to the second inventive example is represented by a range of frequencies, ranging from frequencies f7 to f8 (not shown), wherein the frequencies are related to each other as follows: f7<f1<f0, f0<f2<f8.

It can also be seen from FIG. 13 that the mismatch attenuation of the delay line 100B according to the second inventive example is 20 dB or greater within the range from frequencies f1 through f2, and that the reflected energy is lower than that in the comparative example, similar to the case of the first inventive example.

A review of the flatness of the absolute delay time of the delay line 100B according to the second inventive example indicates that a region (flat region), in which the deviation from the absolute delay time at the central frequency f0 of the passband falls within 0.5 ns, occupies about 65% of the passband, which is much larger than the 30% value achieved according to the comparative example, for all curves D1 through D3.

### INVENTIVE EXAMPLE 3

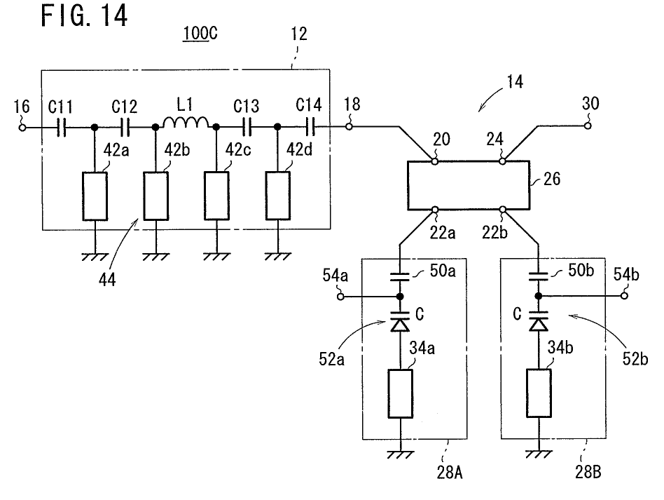

Another inventive example of the delay line 10B according to the second embodiment (a delay line 100C according to a third inventive example) shall be described below with reference to FIGS. 14 through 17.

The delay line 100C according to the third inventive example is of essentially the same structure as the delay line 100B according to the second inventive example. However, as shown in FIG. 14, the first delay circuit 12 differs as follows:

In the first delay circuit 12, a first input terminal 16 and a first resonator 42a adjacent to the first input terminal 16 are connected to each other by a capacitor C11, and the first resonator 42a and a second resonator 42b adjacent to the first resonator 42a are connected to each other by a capacitor C12. The second resonator 42b and a third resonator 42c adjacent to the second resonator 42b are connected to each other by an inductor L1. The third resonator 42c and a fourth resonator 42d adjacent to the third resonator 42c are connected to each other by a capacitor C13, and the fourth resonator 42d and an output terminal 18 are connected to each other by a capacitor C14. Thus, a symmetrical array of four capacitive couplings and a single inductive coupling is provided.

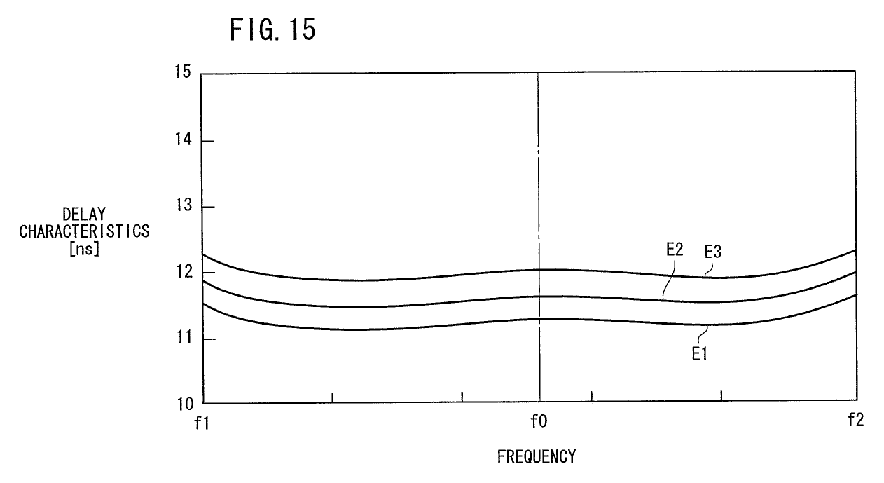

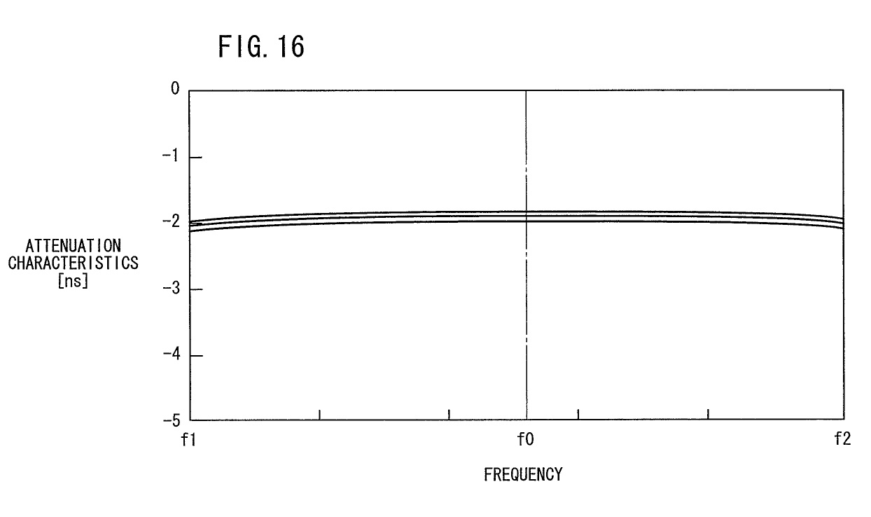

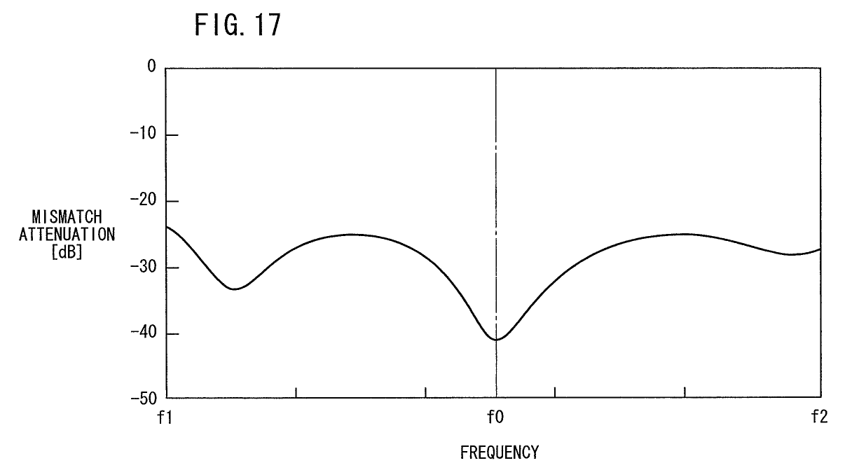

The delay line 100C according to the third inventive example has delay characteristics as shown in FIG. 15, and attenuation characteristics as shown in FIG. 16. The mismatch attenuation of the delay line 100C is changed with respect to frequency as shown in FIG. 17. In FIGS. 15 through 17, the characteristics are shown within a range of frequencies, from frequencies f1 through f2. In FIGS. 15 through 17, curve E1 represents characteristics when the coupling capacitance C of each of the first and second varactor diodes 52a, 52b is C1, curve E2 represents characteristics when the coupling capacitance C is C2, and curve E3 represents characteristics when the coupling capacitance C is C3. The capacitances are related to each other as follows: C1>C2>C3.

It can be seen from FIG. 16 that the delay line 100C according to the third inventive example also has a passband, which is wider than the range from frequencies f1 through f2, because the signal does not fall 3 dB from the value at the central frequency f0 within the range of frequencies from frequencies f1 through f2. Specifically, the passband of the delay line 100C according to the third inventive example is represented by a range of frequencies, ranging from frequencies f9 to f10 (not shown), wherein the frequencies are related to each other as follows: f9<f1<f0 and f0<f2<f10.

It can also be seen from FIG. 17 that the mismatch attenuation of the delay line 100C according to the third inventive example is 20 dB or greater within the range from frequencies f1 through f2, and that the reflected energy is lower than that in the second inventive example, because the mismatch attenuation within a higher-frequency range of the passband is large as compared with the second inventive example.

As shown in FIG. 15, the flatness of the absolute delay time of the delay line 100C according to the third inventive example shows that a deviation in the higher-frequency range of the passband is smaller, as compared with that of the second inventive example. The flat region according to the third inventive example is about 70% of the passband, for all curves D1 through D3, and therefore is better than that of the second inventive example.

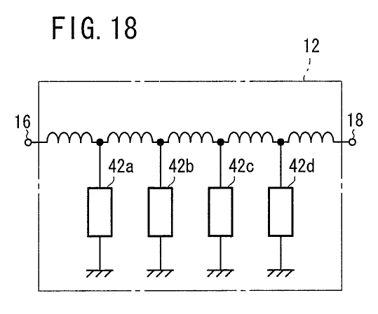

In the inventive examples 1 and 2 described above, the bandpass filter 44 of the first delay circuit 12 comprises the first input terminal 16 and the first resonator 42a, the fourth resonator 42d and the output terminal 18, and the resonators 42a through 42d, which are connected to each other by respective capacitors C11, C12, C13, C14, C15. However, as shown in FIG. 18, the first input terminal 16 and the first resonator 42a, the fourth resonator 42d and the output terminal 18, and the resonators 42a through 42d may also be connected to each other by respective inductances L11, L12, L13, L14, L15.

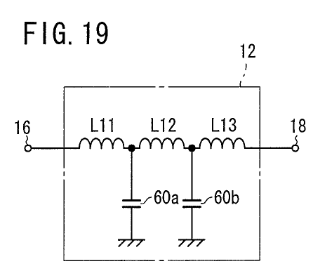

In the above inventive examples 1 through 3, the first delay circuit 12 comprises a bandpass filter 44. However, the first delay circuit 12 may comprise a low-pass filter, a circuit having a delay caused by a stripline length, or a SAW delay line. Such an example is illustrated in FIG. 19.

In the example of the delay circuit 12 shown in FIG. 19, a first capacitor 60a and a second capacitor 60b (both having ends connected to ground) are disposed between the first input terminal 16 and the output terminal 18. Further, the first input terminal 16 and the first capacitor 60a, the second capacitor 60b and the output terminal 18, and the capacitors 60a, 60b are connected to each other by respective inductances L11, L12, L13.

The delay line according to the present invention is not limited to the above embodiments, but may have various structures without departing from the scope of the present invention.

1. A delay line comprising:
a first delay circuit including a first input terminal and an output terminal; and
a second delay circuit comprising a hybrid coupler including a second input terminal, a first output terminal, a second output terminal, and an isolation terminal, a first reactance unit connected to said first output terminal, and a second reactance unit connected to said second output terminal,
wherein said output terminal of said first delay circuit and said second input terminal of said hybrid coupler of said second delay circuit are electrically connected to each other.

2. A delay line according to claim 1, wherein said first delay circuit and said second delay circuit are integrally combined with each other.

3. A delay line according to claim 1, wherein said first reactance unit and said second reactance unit of said second delay circuit include respective reactance elements having constant reactances.

4. A delay line according to claim 1, wherein said first reactance unit and said second reactance unit of said second delay circuit include respective control terminals to which control voltages are applied, and respective variable reactance elements having reactances that are variable depending on said control voltages applied to said control terminals.

5. A delay line according to claim 1, wherein said first delay circuit comprises a bandpass filter.

6. A delay line according to claim 5, wherein said first delay circuit comprises a bandpass filter including a plurality of resonators between said first input terminal and said output terminal.

7. A delay line according to claim 6, wherein said first input terminal and one of said resonators adjacent to said first input terminal, said output terminal and one of said resonators adjacent to said output terminal, and said plurality of resonators are connected to each other by capacitances in said first delay circuit.

8. A delay line according to claim 6, wherein said first input terminal and one of said resonators adjacent to said first input terminal, said output terminal and one of said resonators adjacent to said output terminal, and said plurality of resonators are connected to each other by inductances in said first delay circuit.

9. A delay line according to claim 6, wherein said first input terminal and one of said resonators adjacent to said first input terminal are connected to each other by a capacitance or an inductance, said output terminal and one of said resonators adjacent to said output terminal are connected to each other by a capacitance or an inductance, and said plurality of resonators are connected to each other by capacitances or inductances, thereby providing a symmetrical array of capacitive couplings and inductive couplings in said first delay circuit.

10. A delay line according to claim 1, wherein said first delay circuit comprises at least one of a low-pass filter, a circuit having a delay caused by a stripline length, and a SAW delay line.
